(19) United States
(12) Patent Application Publication
(10) Pub. No.: US 2011/0215426 A1
(43) Pub. Date: Sep. 8, 2011

(54) SEMICONDUCTOR DEVICE AND MANUFACTURING METHOD OF SEMICONDUCTOR DEVICE

(75) Inventors: Yasunori Okayama, Oita (JP); Akihiro Yasumoto, Oita (JP)

(73) Assignee: KABUSHIKI KAISHA TOSHIBA, Tokyo (JP)

(21) Appl. No.: 13/022,918

(22) Filed: Feb. 8, 2011

(30) Foreign Application Priority Data
Mar. 4, 2010 (JP) 2010-048123

(51) Int. Cl. H01L 29/78; H01L 21/336

(52) U.S. Cl. 257/412; 438/301; 257/E29.255; 257/E21.433

(57) ABSTRACT

According to one embodiments, an impurity that is introduced into a gate electrode and includes phosphorus or arsenic, a carbon that is introduced into the gate electrode, and an impurity diffusion layer that is formed in a semiconductor substrate to be arranged on both sides of the gate electrode are included, in which a coverage of an active region in which the gate electrode and the impurity diffusion layer are formed is 50% or more and an area thereof is 0.02 mm² or more.

### CROSS-REFERENCE TO RELATED APPLICATIONS

This application is based upon and claims the benefit of priority from the prior Japanese Patent Application No. 2010-48123, filed on Mar. 4, 2010; the entire contents of which are incorporated herein by reference.

### FIELD

Embodiments described herein relate generally to a semiconductor device and a manufacturing method of the semiconductor device.

### BACKGROUND

In a field-effect transistor formed on a semiconductor device, polycrystalline silicon is typically used as a material of a gate electrode. For controlling conductivity of the gate electrode, impurities such as phosphorus are implanted into polycrystalline silicon.

When a thermal treatment such as activation annealing is performed, impurities such as phosphorus are segregated at the end portion of the gate electrode and the impurities such as phosphorus damage a gate dielectric film, so that increase in local gate leakage may be caused.

Moreover, for example, Japanese Patent Application Laid-Open No. 2006-294841 discloses a method in which for suppressing leakage current in a gate edge portion, after ion-implanting impurities in a semiconductor substrate through a residual film of a tunnel film, the residual film of the tunnel film is removed and a protection film is formed on a sidewall of a floating gate by thermal oxidation.

### BRIEF DESCRIPTION OF THE DRAWINGS

FIG. 1A to FIG. 1E are cross-sectional views illustrating a manufacturing method of a semiconductor device according to a first embodiment;

FIG. 2A is a plan view illustrating an example of closely-arranged circuit blocks;

FIG. 2B is a diagram illustrating a temperature distribution in activation annealing of the circuit blocks shown in FIG. 2A;

FIG. 2C is a diagram illustrating a temperature difference distribution in the activation annealing of the circuit blocks shown in FIG. 2A;

FIG. 3A is a plan view illustrating an example of widely-arranged circuit blocks;

FIG. 3B is a diagram illustrating a temperature distribution in the activation annealing of the circuit blocks shown in FIG. 3A;

FIG. 3C is a diagram illustrating a temperature difference distribution in the activation annealing of the circuit blocks shown in FIG. 3A;

FIG. 4A to FIG. 4F are cross-sectional views illustrating a manufacturing method of a semiconductor device according to a second embodiment; and

FIG. 5A to FIG. 5G are cross-sectional views illustrating a manufacturing method of a semiconductor device according to a third embodiment.

### DETAILED DESCRIPTION

In general, according to one embodiment, a gate electrode that is formed on a semiconductor substrate via a gate dielectric film, an impurity that is introduced into the gate electrode and includes phosphorus or arsenic, a carbon that is introduced into the gate electrode, and an impurity diffusion layer that is formed in the semiconductor substrate to be arranged on both sides of the gate electrode are provided. A coverage of an active region in which the gate electrode and the impurity diffusion layer are formed is 50% or more and an area thereof is 0.02 mm² or more.

Exemplary embodiments of a semiconductor device will be explained below in detail with reference to the accompanying drawings. The present invention is not limited to these embodiments.

### First Embodiment

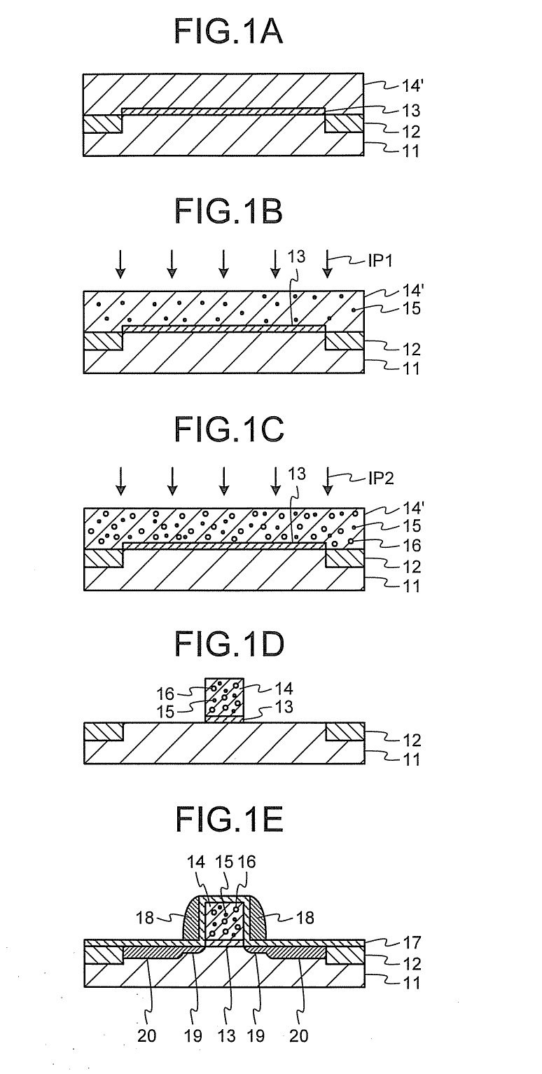

FIG. 1A to FIG. 1E are cross-sectional views illustrating a manufacturing method of a semiconductor device according to the first embodiment.

In FIG. 1A, an isolation layer 12 is formed in a semiconductor substrate 11. As a material of the semiconductor substrate 11, for example, Si, Ge, SiGe, GaAs, InP, GaP, GaN, SiC, and GaInAsP can be used. As the isolation layer 12, an STI (Shallow Trench Isolation) can be used or a LOCOS (Local Oxidation Of Silicon) can be used. Moreover, as a material of the isolation layer 12, for example, a silicon oxide film can be used.

Next, a gate dielectric film 13 is formed on the semiconductor substrate 11 separated by the isolation layer 12. As a material of the gate dielectric film 13, a silicon oxide film can be used or a high dielectric film such as PLZT can be used. Moreover, the film thickness of the gate dielectric film 13 is preferably 1.4 nm or less. Next, a polycrystalline silicon film 14′ is formed on the gate dielectric film 13 by using a method such as the CVD.

Next, as shown in FIG. 1B, ion implantation IP1 is performed on the polycrystalline silicon film 14′ to introduce carbon 15 into the polycrystalline silicon film 14′. The concentration of the carbon 15 is preferably set in a range of 5E19 to 3E20/cm³. For example, as the condition of the ion implantation IP1, when the film thickness of the polycrystalline silicon film 14′ is 80 nm, preferably, an acceleration voltage is set in a range of 4 to 8 keV and a dose amount is set in a range of 1E15 to 3E15 cm⁻².

If the acceleration voltage is too low, the effect of reducing gate leakage is eliminated, and if the acceleration voltage is too high, TDDB (Time Dependent Dielectric Breakdown) occurs. If the dose amount is too low, the effect of reducing the gate leakage is eliminated, and if the dose amount is too high, the gate leakage is rather increased.

Next, as shown in FIG. 1C, ion implantation IP2 is performed on the polycrystalline silicon film 14′ to introduce phosphorus 16 into the polycrystalline silicon film 14′. It is applicable to use arsenic in addition to the phosphorus 16.

Next, as shown in FIG. 1D, the polycrystalline silicon film 14′ is patterned by using a photolithography technology and an etching technology to form a gate electrode 14 on the gate dielectric film 13.

Next, as shown in FIG. 1E, an offset dielectric film 17 is formed on the semiconductor substrate 11 by using a method such as the CVD so that the gate electrode 14 is covered. As the offset dielectric film 17, for example, a silicon oxide film can be used. Moreover, the film thickness of the offset dielectric film 17 can be set to correspond to the diffusion amount of an LDD layer 19 in a lateral direction after the LDD layer 19 is formed.

Next, the ion implantation is performed on the semiconductor substrate 11 with the gate electrode 14 on the sidewall of which the offset dielectric film 17 is formed as a mask to form the LDD layer 19 in the semiconductor substrate 11.

Next, a sidewall 18 is formed on the sidewall of the gate electrode 14 via the offset dielectric film 17. Then, the ion implantation is performed on the semiconductor substrate 11 with the sidewall 18 and the gate electrode 14 as a mask to form a high-concentration impurity diffusion layer 20 in the semiconductor substrate 11, thereby forming a source/drain layer arranged on both sides of the gate electrode 14 in the semiconductor substrate 11. Then, the source/drain layer is activated by performing the thermal treatment of the source/drain layer, for example, by a method such as spike lamp annealing or flash lamp annealing.

When the thermal treatment such as the flash lamp annealing is performed on a device region having a specific integration density or more, the temperature of a specific region rises extremely.

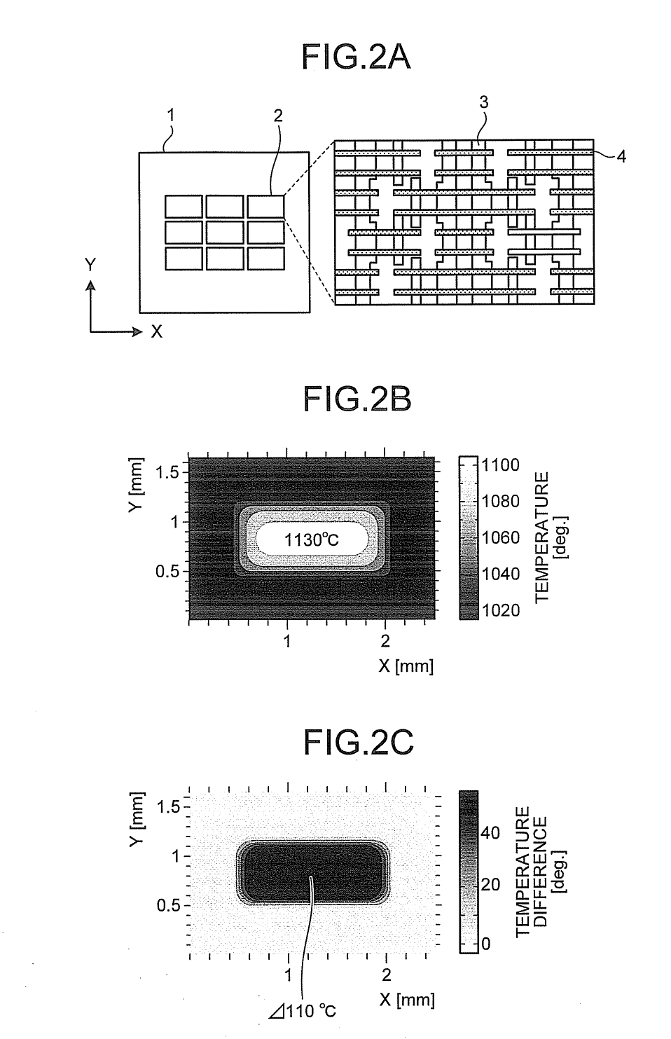

FIG. 2A is a plan view illustrating an example of closely-arranged circuit blocks, FIG. 2B is a diagram illustrating a temperature distribution in activation annealing of the circuit blocks shown in FIG. 2A, and FIG. 2C is a diagram illustrating a temperature difference distribution in the activation annealing of the circuit blocks shown in FIG. 2A.

In FIG. 2A, circuit blocks 2 are formed in a semiconductor substrate 1 and the circuit blocks 2 are closely arranged. The circuit block 2 is provided with an impurity diffusion layer 3 and a gate electrode 4, and an active region is formed at a specific integration density or more with the impurity diffusion layer 3 and the gate electrode 4. The impurity diffusion layer 3 can be used as a source/drain layer of a transistor.

When the thermal treatment for activating the impurity diffusion layer 3 is performed on the semiconductor substrate 1 in which such circuit blocks 2 are arranged, as shown in FIG. 2B, the temperature of the portion of the circuit blocks 2 becomes higher than the temperature therearound, and, as shown in FIG. 2C, the temperature difference distribution is generated.

The generation of such temperature difference distribution is considered to be because thermal energy applied to the semiconductor substrate 1 changes due to diffraction effect of light that depends on a pattern size and a density. It is considered that the temperature rises significantly compared to other regions as a pitch of a pattern becomes narrow with respect to the wavelength of light.

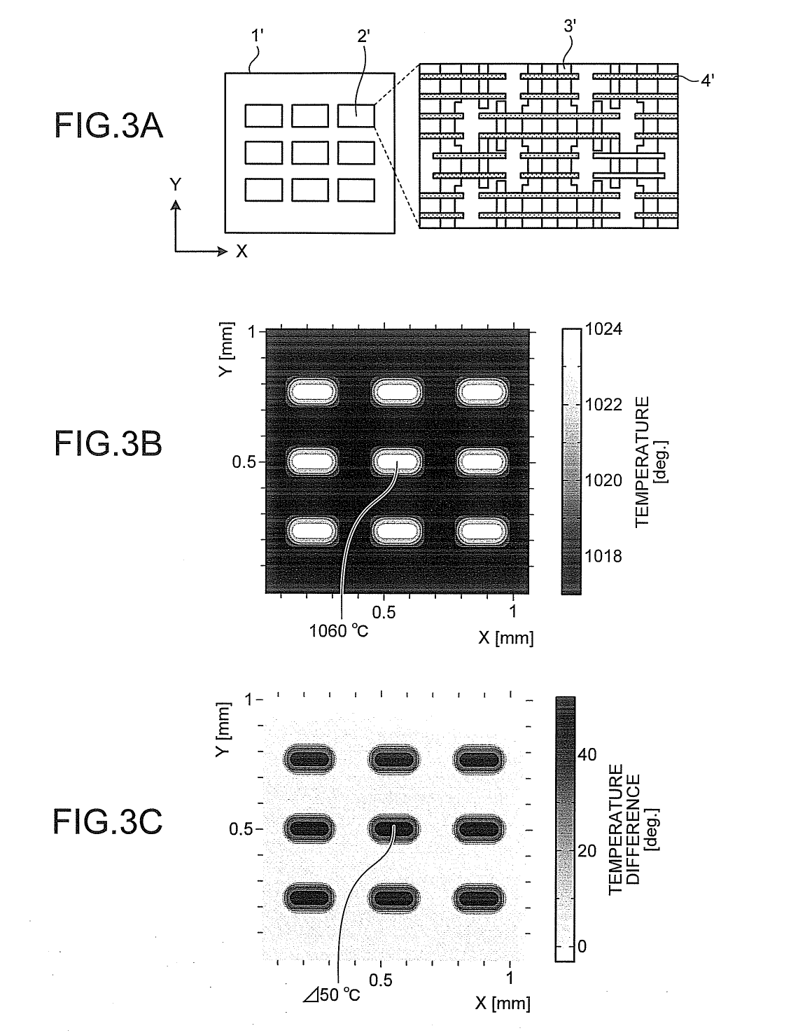

FIG. 3A is a plan view illustrating an example of widely-arranged circuit blocks, FIG. 3B is a diagram illustrating a temperature distribution in the activation annealing of the circuit blocks shown in FIG. 3A, and FIG. 3C is a diagram illustrating a temperature difference distribution in the activation annealing of the circuit blocks shown in FIG. 3A.

In FIG. 3A, circuit blocks 2′ are formed in the semiconductor substrate 1′ and the circuit blocks 2′ are widely arranged. The circuit block 2′ is provided with an impurity diffusion layer 3′ and a gate electrode 4′, and an active region is formed at a specific integration density or more with the impurity diffusion layer 3′ and the gate electrode 4′.

When the thermal treatment for activating the impurity diffusion layer 3′ is performed on the semiconductor substrate 1′ in which such circuit blocks 2′ are arranged, as shown in FIG. 3B, the temperature of the portion of the circuit blocks 2′ becomes higher than the temperature therearound, and, as shown in FIG. 3C, the temperature difference distribution is generated. In the example in FIG. 3A to FIG. 3C, the circuit blocks 2′ are arranged widely compared to the example in FIG. 2A to FIG. 2C, so that the temperature difference is small.

In this manner, when the activation annealing is performed, the temperature rises significantly in the device region having a specific integration density or more compared to other regions. In the device region having a specific integration density or more, the gate leakage locally increases due to diffusion of the phosphorus 16 at the gate edge and thus the transistor characteristics vary.

Moreover, in the device region having a specific integration density or more, because the number of transistors is large, the number of transistors that are affected by increase in the local gate leakage also becomes large, so that the probability to be detected as a bit failure becomes high.

Therefore, if a large number of transistors are mounted at a high integration density such as a large-capacity SRAM, a transistor that is detected as a bit failure increases due to increase in the local gate leakage, so that the yield decreases.

On the contrary, the phosphorus 16 in the gate electrode 14 can be suppressed from diffusing by introducing the carbon 15 into the gate electrode 14 with respect to the device region having a specific integration density or more. Therefore, even when the thermal treatment such as the activation annealing is performed, it is possible to suppress that the phosphorus 16 is segregated at the end portion of the gate electrode 14 and the phosphorus 16 damages the gate dielectric film 13, enabling to reduce increase in the local gate leakage.

The probability of causing increase in the local gate leakage is low in the case of one transistor, so that, in an integrated circuit on which a small number of transistors are mounted at a low integration density, there is little influence on the yield decrease even if the above described countermeasure against the gate leakage is not performed.

On the contrary, in an integrated circuit on which a large number of transistors are mounted at a high integration density such as a large-capacity SRAM, the probability of causing increase in the local gate leakage in any of the transistors becomes high, so that it is detected as a single bit failure, which largely contributes as a factor of decreasing the yield. Therefore, it is preferable that the above described countermeasure against the gate leakage be applied to an integrated circuit on which a large number of transistors are mounted such as a large-capacity SRAM or a large-scale logic circuit. Specifically, it is preferable that the above described countermeasure against the gate leakage be applied to an integrated circuit in which coverage of an active region in which the gate electrode is formed is 50% or more and a region in which the area thereof is 0.02 mm² or more is arranged.

Moreover, when the film thickness of the gate dielectric film 13 is larger than 1.4 nm, even if diffusion of the phosphorus 16 occurs at the gate edge, the gate leakage hardly increases locally. Therefore, the effect of reducing the gate leakage by introducing the carbon 15 into the gate electrode 14 appears remarkably in the case where the film thickness of the gate dielectric film 13 is 1.4 nm or less.

### Second Embodiment

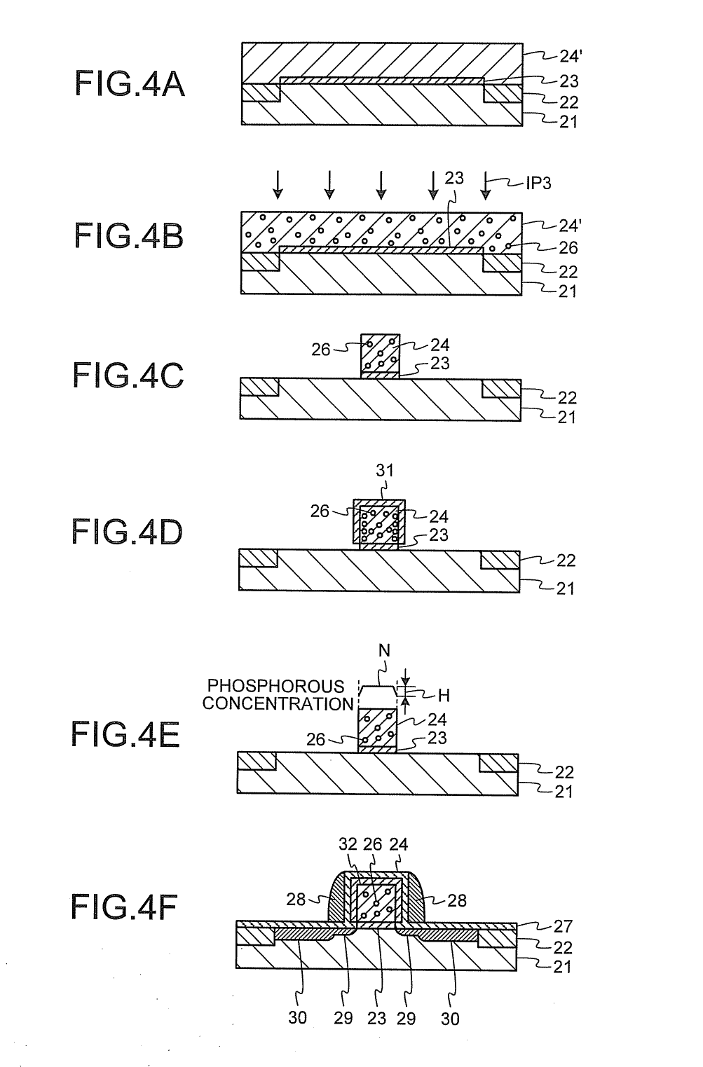

FIG. 4A to FIG. 4F are cross-sectional views illustrating a manufacturing method of a semiconductor device according to the second embodiment.

In FIG. 4A, an isolation layer 22 is formed in a semiconductor substrate 21. Next, a gate dielectric film 23 is formed on the semiconductor substrate 21 separated by the isolation layer 22. The film thickness of the gate dielectric film 23 is preferably 1.4 nm or less. Next, a polycrystalline silicon film 24′ is formed on the gate dielectric film 23 by using a method such as the CVD.

Next, as shown in FIG. 4B, ion implantation IP3 is performed on the polycrystalline silicon film 24′ to introduce phosphorus 26 into the polycrystalline silicon film 24′. It is applicable to use arsenic in addition to the phosphorus 26.

Next, as shown in FIG. 4C, the polycrystalline silicon film 24′ is patterned by using the photolithography technology and the etching technology to form a gate electrode 24 on the gate dielectric film 23.

Next, as shown in FIG. 4D, thermal oxidation is performed on the surface of the gate electrode 24 to form an oxide film 31 on the surface of the gate electrode 24 and segregate the phosphorus 26 at the end portion of the gate electrode 24.

Next, as shown in FIG. 4E, the phosphorus 26 segregated at the end portion of the gate electrode 24 and the oxide film 31 formed on the surface of the gate electrode 24 are removed by using a method such as a wet etching or a plasma etching. A concentration distribution N of the phosphorus 26 of the gate electrode 24 after removing the phosphorus 26 segregated at the end portion of the gate electrode 24 is such that the concentration becomes low in the end portion compared to the central portion of the gate electrode 24. A decreasing rate H of the concentration of the phosphorus 26 at the end portion with respect to the impurity concentration at the central portion of the gate electrode 24 is preferably 20% or more.

Next, as shown in FIG. 4F, the thermal oxidation is performed on the surface of the gate electrode 24 to reattach an oxide film 32 to the surface of the gate electrode 24.

Next, an offset dielectric film 27 is formed on the semiconductor substrate 21 by using a method such as the CVD so that the gate electrode 24 is covered.

Next, the ion implantation is performed on the semiconductor substrate 21 with the gate electrode 24 on the sidewall of which the offset dielectric film 27 is formed as a mask to form an LDD layer 29 in the semiconductor substrate 21.

Next, a sidewall 28 is formed on the sidewall of the gate electrode 24 via the offset dielectric film 27. Then, the ion implantation is performed on the semiconductor substrate 21 with the sidewall 28 and the gate electrode 24 as a mask to form a high-concentration impurity diffusion layer 30 in the semiconductor substrate 21, thereby forming a source/drain layer arranged on both sides of the gate electrode 24 in the semiconductor substrate 21. Then, the source/drain layer is activated by performing the thermal treatment of the source/drain layer, for example, by a method such as the spike lamp annealing or the flash lamp annealing.

After segregating the phosphorus 26 at the end portion of the gate electrode 24 by the thermal oxidation, the segregated phosphorus 26 is removed, so that even when the thermal treatment such as the activation annealing is performed thereafter, diffusion of the phosphorus 26 in the gate edge can be reduced. Therefore, it is possible to suppress that the phosphorus 26 damages the gate dielectric film 23, enabling to reduce increase in the local gate leakage.

Moreover, in an integrated circuit on which a large number of transistors are mounted at a high integration density such as a large-capacity SRAM, the probability of causing the gate leakage in any of the transistors becomes high. Therefore, it is preferable that the above described countermeasure against the gate leakage be applied to an integrated circuit on which a large number of transistors are mounted such as a large-capacity SRAM or a large-scale logic circuit. Specifically, it is preferable that the above described countermeasure against the gate leakage be applied to an integrated circuit in which coverage of an active region in which the gate electrode is formed is 50% or more and a region in which the area thereof is 0.02 mm² or more is arranged.

### Third Embodiment

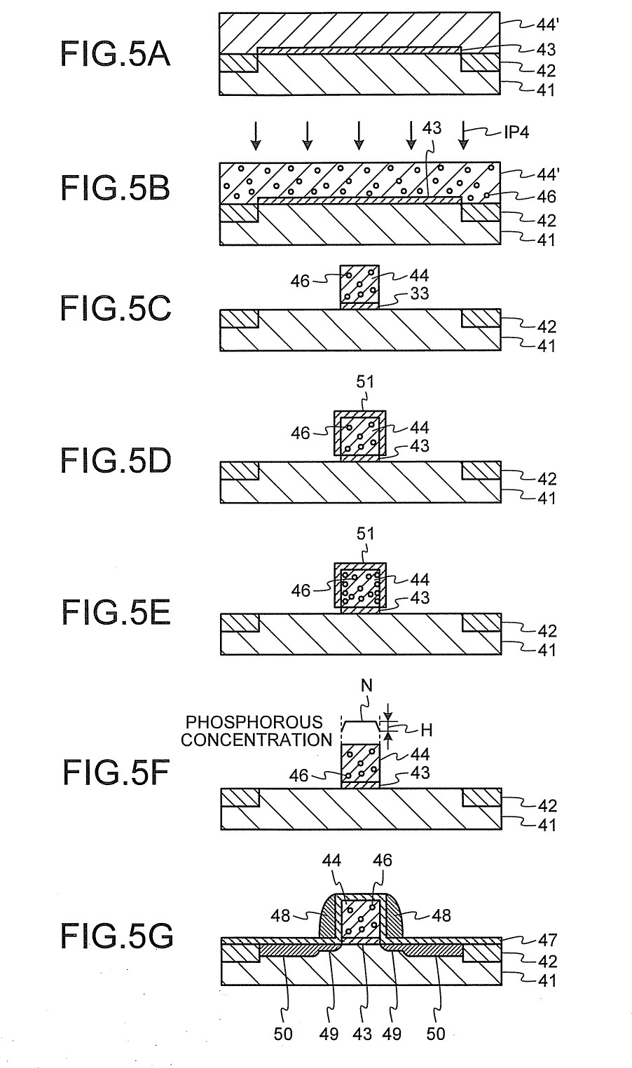

FIG. 5A to FIG. 5G are cross-sectional views illustrating a manufacturing method of a semiconductor device according to the third embodiment.

In FIG. 5A, an isolation layer 42 is formed in a semiconductor substrate 41. Next, a gate dielectric film 43 is formed on the semiconductor substrate 41 separated by the isolation layer 42. The film thickness of the gate dielectric film 43 is preferably 1.4 nm or less. Next, a polycrystalline silicon film 44′ is formed on the gate dielectric film 43 by using a method such as the CVD.

Next, as shown in FIG. 5B, ion implantation IP4 is performed on the polycrystalline silicon film 44′ to introduce phosphorus 46 into the polycrystalline silicon film 44′. It is applicable to use arsenic instead of the phosphorus 46.

Next, as shown in FIG. 5C, the polycrystalline silicon film 44′ is patterned by using the photolithography technology and the etching technology to form a gate electrode 44 on the gate dielectric film 43.

Next, as shown in FIG. 5D, the thermal oxidation is performed on the surface of the gate electrode 44 to form an oxide film 51 on the surface of the gate electrode 44.

Next, as shown in FIG. 5E, the phosphorus 46 is segregated at the end portion of the gate electrode 44 by performing the thermal treatment on the gate electrode 44. The thermal treatment of the gate electrode 44 is preferably performed at the temperature of 1000° C. or more. Moreover, as this thermal treatment, a spike RTA (Rapid Thermal Anneal), an MSA (Millisec Anneal), or the flash lamp annealing can be used.

Next, as shown in FIG. 5F, the phosphorus 46 segregated at the end portion of the gate electrode 44 and the oxide film 51 formed on the surface of the gate electrode 44 are removed by using a method such as the wet etching or the plasma etching. The concentration distribution N of the phosphorus 46 of the gate electrode 44 after removing the phosphorus 46 segregated at the end portion of the gate electrode 44 is such that the concentration becomes low in the end portion compared to the central portion of the gate electrode 44. The decreasing rate H of the concentration of the phosphorus 46 at the end portion with respect to the concentration of the phosphorus 46 at the central portion of the gate electrode 44 is preferably 20% or more.

Next, as shown in FIG. 5G, an offset dielectric film 47 is formed on the semiconductor substrate 41 by using a method such as the CVD so that the gate electrode 44 is covered.

Next, the ion implantation is performed on the semiconductor substrate 41 with the gate electrode 44 on the sidewall of which the offset dielectric film 47 is formed as a mask to form an LDD layer 49 in the semiconductor substrate 41.

Next, a sidewall 48 is formed on the sidewall of the gate electrode 44 via the offset dielectric film 47. Then, the ion implantation is performed on the semiconductor substrate 41 with the sidewall 48 and the gate electrode 44 as a mask to form a high-concentration impurity diffusion layer 50 in the semiconductor substrate 41, thereby forming a source/drain layer arranged on both sides of the gate electrode 44 in the semiconductor substrate 41. Then, the source/drain layer is activated by performing the thermal treatment of the source/drain layer, for example, by a method such as the spike lamp annealing or the flash lamp annealing.

After segregating the phosphorus 46 at the end portion of the gate electrode 44 by the thermal treatment, the segregated phosphorus 46 is removed, so that even when the thermal treatment such as the activation annealing is performed thereafter, it is possible to suppress that the phosphorus 46 damages the gate dielectric film 43, enabling to reduce increase in the local gate leakage.

Moreover, in an integrated circuit on which a large number of transistors are mounted at a high integration density such as a large-capacity SRAM, the probability of causing the gate leakage in any of the transistors becomes high. Therefore, it is preferable that the above described countermeasure against the gate leakage be applied to an integrated circuit on which a large number of transistors are mounted such as a large-capacity SRAM or a large-scale logic circuit. Specifically, it is preferable that the above described countermeasure against the gate leakage be applied to an integrated circuit in which coverage of an active region in which the gate electrode is formed is 50% or more and a region in which the area thereof is 0.02 mm² or more is arranged.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a gate electrode that is formed on a semiconductor substrate via a gate dielectric film;
an impurity that is introduced into the gate electrode and includes phosphorus or arsenic;
a carbon that is introduced into the gate electrode; and
an impurity diffusion layer that is formed in the semiconductor substrate to be arranged on both sides of the gate electrode, wherein
a coverage of an active region in which the gate electrode and the impurity diffusion layer are formed is 50% or more and an area thereof is 0.02 mm² or more.

2. The semiconductor device according to claim 1, wherein a concentration of the carbon is in a range of 5E19 to 3E20/cm³.

3. The semiconductor device according to claim 1, wherein a film thickness of the gate dielectric film is 1.4 nm or less.

4. The semiconductor device according to claim 1, wherein transistors formed in the active region are integrated.

5. A semiconductor device comprising:
a gate electrode that is formed on a semiconductor substrate via a gate dielectric film;
an impurity that is distributed so that a concentration becomes low in an end portion compared to a central portion of the gate electrode and includes phosphorus or arsenic; and
an impurity diffusion layer that is formed in the semiconductor substrate to be arranged on both sides of the gate electrode, wherein
a coverage of an active region in which the gate electrode and the impurity diffusion layer are formed is 50% or more and an area thereof is 0.02 mm² or more.

6. The semiconductor device according to claim 5, wherein an impurity concentration at the end portion of the gate electrode is lower than an impurity concentration at the central portion of the gate electrode by 20% or more.

7. The semiconductor device according to claim 5, wherein a film thickness of the gate dielectric film is 1.4 nm or less.

8. The semiconductor device according to claim 5, wherein transistors formed in the active region are integrated.

9. A method of manufacturing a semiconductor device comprising:
forming a polycrystalline silicon film on a semiconductor substrate via a gate dielectric film;
implanting an impurity that includes phosphorus or arsenic into the polycrystalline silicon film;
implanting a carbon into the polycrystalline silicon film;
forming a gate electrode by processing the polycrystalline silicon film in which the impurity that includes phosphorus or arsenic and the carbon are implanted; and
forming a source/drain layer arranged on both sides of the gate electrode in the semiconductor substrate by implanting impurity into the semiconductor substrate with the gate electrode as a mask, wherein
a coverage of an active region in which the gate electrode and the source/drain layer are formed is 50% or more and an area thereof is 0.02 mm² or more.

10. The method according to claim 9, further comprising activating the source/drain layer by performing a thermal treatment of the source/drain layer.

11. The method according to claim 10, wherein the thermal treatment of the source/drain layer is a spike lamp annealing or a flash lamp annealing.

12. The method according to claim 9, wherein a concentration of the carbon is in a range of 5E19 to 3E20/cm³.

13. The method according to claim 9, wherein a film thickness of the gate dielectric film is 1.4 nm or less.

14. The method according to claim 9, wherein transistors formed in the active region are integrated.

15. A method of manufacturing a semiconductor device comprising:
forming a polycrystalline silicon film on a semiconductor substrate via a gate dielectric film;
implanting an impurity that includes phosphorus or arsenic into the polycrystalline silicon film;
forming a gate electrode by processing the polycrystalline silicon film in which the impurity that includes phosphorus or arsenic is implanted;
segregating the impurity that includes phosphorus or arsenic at an end portion of the gate electrode by performing a thermal oxidation on a surface of the gate electrode;
removing the impurity segregated at the end portion of the gate electrode and an oxide film formed on the surface of the gate electrode; and
forming a source/drain layer arranged on both sides of the gate electrode in the semiconductor substrate by implanting impurity into the semiconductor substrate with the gate electrode from which the impurity segregated at the end portion is removed as a mask, wherein
a coverage of an active region in which the gate electrode and the source/drain layer are formed is 50% or more and an area thereof is 0.02 mm² or more.

16. The method according to claim 15, further comprising activating the source/drain layer by performing a thermal treatment of the source/drain layer.

17. The method according to claim 16, wherein the thermal treatment of the source/drain layer is a spike lamp annealing or a flash lamp annealing.

18. The method according to claim 15, wherein a concentration of the carbon is in a range of 5E19 to 3E20/cm³.

19. The method according to claim 15, wherein a film thickness of the gate dielectric film is 1.4 nm or less.

20. The method according to claim 15, wherein transistors formed in the active region are integrated.
